(19) United States
(12) Patent Application Publication
(10) Pub. No.: US 2009/0075402 A1
(43) Pub. Date: Mar. 19, 2009

(54) Manipulation of focused heating source based on in situ optical measurements

(76) Inventors: Michel Meunier, Pierrefonds (CA); Stephane Laforte, Granby (CA)

Correspondence Address: Ronald S. Kosie;BCF LLP, 25th Floor, 1100 Rene-Levesque Boulevard West, Montreal, QC, H3B 5C9, CA

(21) Appl. No.: 11/902,027

(22) Filed: Sep. 18, 2007

(51) Int. Cl. H01L 21/00; B23K 26/06

(52) U.S. Cl. 438/7; 219/121.65; 257/E21.001

(57) ABSTRACT

A method, system or the like which may, for example, be exploited as part of known methods, systems and/or apparatii which manipulate (i.e. tune, modify, change, create, etc.) the impedance of (integrated) semiconductor components or devices by exploiting a focused heating source. The method, system or the like exploits in situ optical measurements for the modification of the energy output of a focused heating source, such as for example of a (pulsed) laser heat source. The energy input to the focused heating source may be manipulated as a function of an optical measurement so as to obtain a desired or necessary energy output (e.g. target energy output) from the focused heating source.

The present invention relates to the field of (integrated) semiconductor components or devices which may be of digital and/or analogue type. The present invention, in particular, is directed to a method, system or the like which may, for example, be exploited as part of known methods, systems and/or apparatii which manipulate (i.e. tune, modify, change, create, etc.) the impedance of such semiconductor components or devices by exploiting a focused heating source. In accordance with such known impedance modifying techniques a focused heat source is used for the heat modification of a heat modifiable dopant profile of a target region or the like of a semiconductor component or device. More particularly, the present invention generally relates to a method, system or the like which exploits in situ optical measurements for the modification of the energy output of a focused heating source, such as for example of a (pulsed) laser heat source. In accordance with the present invention, the energy input to the focused heating source may be manipulated as a function of an optical measurement so as to obtain a desired or necessary energy output (e.g. target energy output) from the focused heating source.

It is to be understood herein that the expression “heat modifiable dopant profile” or the like characterizes a region, sub-region, area, location or the like, as being one which may, on the application of a suitable heat source, be melted such that dopant may migrate or diffuse there through so as to alter the dopant profile (i.e. dopant concentration) thereof and provide a new dopant profile which may be maintained on solidification of the melted target region or area.

It is to be understood herein that the word “impedance” relates to both resistance and capacitance, and that modifying the impedance of an integrated semiconductor device is understood to comprise modifying the resistance and/or the capacitance of a semiconductor device or component, as the case may be.

Although the present invention is to be discussed herein, in more detail, by way of example only, in relation to laser type heat sources, it is nevertheless to be understood herein that the expression “focused heating source” or the like as used in accordance with the present invention comprises any (e.g. known) heating source suitable for the purposes herein. Thus in accordance with the present invention it is to be understood herein that the reference to a “focused heating source” or the like, is a reference to any type of heating source of any kind whatsoever whereby one is able to direct, concentrate or apply energy to a predetermined target region, area, location or the like (e.g. a target region or area as described herein) so as to heat the target region or area for the purpose of altering the dopant profile thereof. The focused heating source may for example be a suitably configured device using an electron beam as the energy delivery means. Thus for example the focused heat source may comprise a heating element able to provide a laser type output, an electron beam type output, or the like.

It is also to be understood herein that the expressions “reflectable probe signal”, “reflected probe signal” and the like includes a probe signal based on any type of electromagnetic radiation that is reflectable or reflected from a target region as contemplated by the present invention and this when the target region is in a solid state and/or in a melt state. The electromagnetic radiation may for example be electromagnetic radiation which is visible to the eye (i.e. visible light). The “reflectable probe signal”, “reflected probe signal” and the like, may for example be a laser based signal. It is further to be understood herein that the expressions “reflectable probe signal”, “reflected probe signal” and the like is a reference to a signal that does not interfere or that does not substantially interfere with the functioning of the ‘focused heating source’.

The modification of the impedance of a (integrated) semiconductor device or component through the use of a focused heating source (e.g. such as a laser) is known in the art. Such methods, are sometimes referred to collectively as the (laser) trimming of (integrated) semiconductor components or devices. Trimming is, for example, known to be performed on a semiconductor device or component having a resistive thin film structure and the like.

It is in particular known to exploit a focused heating source (e.g. such as a laser) for (finely) tuning the impedance of (digital and/or analogue) semiconductor components or devices. The tuning may be accomplished by heat modification of the dopant profile of a target location or region of a semiconductor device; e.g. laser pulse(s) may be applied over adjacent regions of heat alterable dopant profiles. The target location or region to be so heat treated, may, for example, comprise at least two sub-regions which have different heat modifiable dopant profiles. For example, the target region may comprise a sub-region of low dopant concentration adjacent a sub-region of higher dopant concentration such that dopant(s) may diffuse from the sub-region of higher dopant concentration to the sub-region of lower dopant concentration due to the melting action of a focused heating source on the target region.

It is known, for example, to apply a laser trimming technique, to a semiconductor device or component which comprises two highly doped regions of one dopant type separated from each other by a gap region. The gap region may not be doped or may be lightly or differently doped in relation to the other regions. The target region may comprise part of each of the highly doped regions (i.e. highly doped sub-regions) as well as part of the gap region (i.e. a gap sub-region). The dopant profile of the target region may be modified by the application of a heat/cooling cycle whereby the target region is caused to pass from a solid state to a liquid state and back to a solid state. The heat/cooling cycle comprises a heat treatment component and a cooling component. In accordance with the heat treatment component an appropriately energized laser beam is focused on the target region so as to cause or induce melting thereof, resulting in dopant diffusion from the highly doped sub-regions to the gap sub-region. Upon termination of the laser energy output, the melted target region is allowed to solidify, leaving the diffused dopants (frozen) in a new distribution so as to form an electrical link between the highly doped sub-regions (i.e. this is the cooling component of the heat/cooling cycle). This laser-diffused link may constitute a trimmed resistor.

It is known, in particular, to selectively tune the impedance (e.g. resistance) of (integrated) semiconductor devices or components, by modifying the dopant profile of a target region by an iterative feedback technique; see for example U.S. Pat. Nos. 6,329,272, 6,890,802 and 7,217,986 the entire contents of each of which is incorporated herein by reference.

To control the resistance value using an iterative process such as shown in the above mentioned patents, an electrical measurement is required after each heat/cooling cycle. By varying the heating process parameters between each heat treatment (i.e. laser energy intervention) and by performing an electrical measurement, one can control the tuning of the device or the circuit. In this approach an electrical measurement or test is performed after each heat/cooling cycle and the heating cycle is repeated with or without modification to the laser pulse until the desired target impedance is achieved.

As may be appreciated many heat treatments or irradiations may need to be performed at different places of a semiconductor component or device (i.e. circuit) in order to create or alter resistances; this may be especially so when dealing with a component or device comprising analogue circuit functionality.

It would be desirable to be able to limit or control the energy applied during heat treatments (i.e. number, intensity, etc.) and to which a semiconductor component or device is subjected since each heat treatment carries with it a risk of undesired heat damage to the semiconductor component, undesired defect production in the semiconductor component and the like. It would also be desirable to be able to optimize the energy applied during the heat treatments to facilitate production of semiconductor components produced in a production line.

It would in particular be advantageous to be able to control the level of the energy output of a focused energy source to be above, below or at a desired target level. It would for example be desirable to be able to direct the energy output of a focused energy source to be (set) at a desired level different from a predetermined target level, i.e. either higher or lower than a predetermined (target) energy level.

As may be understood, it is, in particular, desirable that parts of the semiconductor component or device outside the target region or area not be undesirably affected (e.g. caused to be melted) by the heat treatment exploited to modify the dopant profile of the target region or area, i.e. that the energy actually delivered and applied to a target region be sufficient for dopant modification purposes but not be so high as to undesirably affect surrounding structures. Furthermore, it would also be desirable that the energy output of the focused heating source directed to the target region or area be high enough to achieve a desired rate of change of dopant profile (for production purposes) as well as being low enough to avoid undesirable (heat) damage of the surrounding structure of the (integrated) semiconductor component or device.

For example, semiconductor components or devices may be provided with one or more (e.g. a plurality of) overlying insulating dielectric layers and optionally, as desired or necessary, passivation layer(s). A passivation layer may be provided on the surface of a semiconductor component or device to provide electrical stability by isolating the transistor surface and the electrical circuits from electrical and chemical conditions in the environment. A passivation layer may comprise an oxide layer (such as for example of silicon dioxide). In accordance with the present invention, an overlying dielectric layer or passivation layer (if present) is to be understood herein as being a layer which is transparent (i.e at the wavelength used) to the focused heating source (e.g. to the heating lasers or electron beams) so as to allow the focused heating source to be able to melt a target region as described herein. It is of course to also be understood that any such above mentioned layers has to be also transparent to the reflectable probe beam.

In practice, however, semiconductor components, although nominally the same and even on the same chip, may, for example, nevertheless have (minute) differences in terms of passivation layer thicknesses and even composition. Such variations with respect to composition and/or thicknesss, may lead to laser beam reflection and interference, which may significantly alter (e.g. decrease or even increase) the laser energy output which is actually applied to a given heat modifiable target region notwithstanding that the energy output from the laser energy source may be constant.

As mentioned above it would thus be advantages to have means for the (real time) modification of the energy output of the focused heating source such that the energy output of the focused heating source may approach a predetermined target value which is high enough to achieve a desired rate of change of dopant profile (for production purposes) but yet be low enough to avoid undesirable (heat) damage. It would be advantageous to be able to integrate such energy output control into known trimming operations.

It would also be advantageous to have a method for iteratively, selectively tuning the energy output of the focused heating source which would not necessarily require the taking of an electrical measurement after each heat/cooling cycle (i.e. in order to ultimately obtain a predetermined or desired impedance for the semiconductor component or device).

It is known that irradiating a solid (such as for example solid silicon) with a laser beam so as to provide a melted region or area leads to a significant change in the (optical) reflectivity and absorption of the melted region. As an example, the reflection coefficient of silicon in the solid state is approximately 0.52 at the wavelength of 633 nm whereas at the melting temperature, the reflection coefficient of silicon in the liquid state increases to 0.73 at the same wavelength.

Keeping the above in mind, in a general aspect the present invention relates to a means wherein the energy output of a focused heating source may be adjusted or modified as a function of in situ probe signal measurement (s) which may be taken in real time (rather than solely by electrical (e.g. impedance) measurements as discussed in the above mentioned U.S. patents).

The present invention is based on the realization that an exploitable linkage may be made between the existence of the melted region or area, the reflective intensity of a reflected probe signal produced by a probe output signal applied to (or incident on) the melted region or area, the energy input to the focused heating source and the energy output of the focused heating source.

The present invention therefore, keeping the above in mind, proposes to exploit in situ probe (e.g. optical) signal measurement(s) to obtain information on the melt state of the target region with respect to which the dopant profile is to be modified. Since this in situ measurement may be performed during the irradiation, it would not slow down the trimming process.

The in situ probe (e.g. optical) signal measurement may, for example, used as part of an iterative loop the goal of which is to modify (as necessary) the energy output of the focused heating source (i.e. modify the irradiation beam power) in order to obtain a desired predetermined optical measurement, and thus a desired or necessary predetermined targeted focused energy output from the focused heating source.

Thus the present invention more particularly relates to control means (i.e. for a system, method, etc.) for controlling the modification of the energy output from the focused heating source to the target region or area of the semiconductor component. In accordance with the present invention such control may be based on in situ probe (e.g. optical) signal measurement (s) taken for the purpose of obtaining reflection signal information with respect to the melt state of the target region based on the start time of the application of the output energy of the focused heating source, i.e. based on probe (e.g. optical) signal measurements taken in real time. Based on this real time information (and, if necessary or desired, using an iterative loop such as exemplified in the above mentioned U.S. patents), the in situ probe (e.g. optical) signal measurement may provide an observed signal in response to which the energy output from the focused heating source may be modified (for example for modifying the output irradiation beam pulsation power, output pulsation duration, output pulse temporal shape (e.g a saw-tooth shape, sinusoidal shape, square shape, etc.)) in order to obtain a reflective optical measurement (i.e. observed signal as described herein) indicative of the attainment of a desired or necessary (i.e. predetermined or target) energy output from the focused heating source.

The present invention in accordance with an aspect thereof provides a system for the controlled dopant profile modification of a pre-selected target region (or location) of a semiconductor component by the application of one or more heat treatments to said pre-selected target region (or location), wherein said pre-selected target region (or location) comprises a first region contiguous with a second region, said first region having a heat modifiable dopant profile, said second region having a heat modifiable dopant profile different from said first region,

said system comprising a heat treatment component comprising a focused heating source for providing a focused energy output (e.g. such as a heating element comprising a laser), said heat treatment component being configured for subjecting said pre-selected region (or location) to a heat treatment wherein [e.g. in response to a pre-determined energy input to the heat treatment component] said focused energy output (e.g. a heating laser energy output)
is directed [i.e. from said heat treatment component] to said pre-selected target region (or location) for a pre-determined duration having a start time and a finish time and
is sufficient to melt said pre-selected target region (or location) to form a melted region in a melt state

so as to thereby alter the dopant profile of the melted preselected target region (or location),

characterized in that said system comprises a probe component for producing a control signal as a function of a reflected probe signal (e.g. a reflected optical signal such as for example a reflected probe laser signal) from said melted region, said probe control component comprising:
a) a probe (i.e. optical or light) signal generating component for directing a (e.g. continuous, or pulsed (if pulsed then e.g. with pulse width/time longer than a heating pulse) probe output signal (e.g. laser probe output signal) to said pre-selected target region (or location);

and
b) a reflected probe (e.g. optical or light ) signal controller component comprising
   i) a probe signal (e.g. optical signal) detector element for receiving a reflected probe (e.g. light) signal generated by said probe output signal at said pre-selected target region (or location) (i.e. a reflected signal generated by the incident probe output signal), and for converting said reflected probe (e.g. light) signal to an observed electronic signal initiated at said start time; and
   ii) an electronic signal analyzer element for comparing said observed electronic signal with a predetermined target reflection signal having a target melt component indicative of said melted state, to determine if said observed electronic signal has a respective melt component which is synchronous or asynchronous (i.e. in phase or out of phase) with the target melt component of said predetermined target reflection signal, said electronic signal analyzer element producing at least one control signal selected from the group consisting of a leading signal if the melt component of said observed electronic signal leads the target melt component of said predetermined target reflection signal and a lagging signal if the melt component of said observed electronic signal lags the target melt component of said predetermined target reflection signal.

In accordance with the present invention a system (or method) as described herein may as desired or necessary be configured so as to produce only a leading signal, only a lagging signal or as the case may be a leading signal as well as a lagging signal. For example, if it is desired or necessary only to avoid the application of a too high focused energy output from the focused energy source then the system need only be configured to provide a leading electronic signal. On the other hand if it is only desired or necessary to avoid a too low focused energy output from the focused energy source then the system need only be configured to provide a lagging electronic signal. On the other hand, if it is desired to not only to avoid the application of a too high focused energy output but also a too low energy output from the focused energy source then the system may be configured to provide for both a leading electronic signal and a lagging signal; in this last case, an iterative set of heat treatments (such as described, for example, in the above mentioned U.S. patents ) may be exploited for placing the focused energy output at or at least substantially at a target focused energy output. As discussed herein a system (or method) of the present invention may, optionally, further provide as desired or necessary a NUL signal indicative of the suitability of a particular focused energy output of a focused energy source (i.e. a signal to a control unit giving an indication that no change need be made to the heat output settings of a focused heating source).

In accordance with the present invention a system as described herein may comprise a probe component which is a probe control component for controlling said heat treatment component as a function of said reflected probe signal from said melted region and which further comprises an electronic control element for directing said heat treatment component, when said heat treatment is repeated (e.g. one or more times—after suitable cooling of a target region after any previous heat treatment), to manipulate or modify, in response to said control signal and in predetermined manner, the focused energy output for a subsequent heat treatment.

In accordance with the present invention a probe (i.e. optical or light) signal generating component may comprise
i) a probe signal directing element and
i) a probe signal generating element for providing an (e.g. continuous or pulsed (if pulsed then e.g. with pulse width or time duration longer than the heating pulse) output signal to said probe signal directing element for directing a probe output signal to said pre-selected target region (or location).

In accordance with the present invention a system is provided wherein said electronic signal analyzer element produces a leading signal if the melt component of said observed electronic signal leads the target melt component of said predetermined target reflection signal.

In accordance with the present invention a system is provided wherein said electronic signal analyzer element produces a lagging signal if the melt component of said observed electronic signal lags the target melt component of said predetermined target reflection signal.

In accordance with the present invention a system is provided wherein said electronic signal analyzer element produces a leading signal if the melt component of said observed electronic signal leads the target melt component of said predetermined target reflection signal and a lagging signal if the melt component of said observed electronic signal lags the target melt component of said predetermined target reflection signal.

In accordance with the present invention a system is provided wherein said probe component is a probe control component for controlling said heat treatment component as a function of said reflected probe signal from said melted region and which further comprises one of the following, namely
an electronic control element for directing said heat treatment component, when said heat treatment is repeated (e.g. one or more times—after suitable cooling of a target region after any previous heat treatment), to decrease said focused energy output for a subsequent heat treatment in a predetermined manner in response to a leading electronic signal;
an electronic control element for directing said heat treatment component, when said heat treatment is repeated (e.g. one or more time—after suitable cooling of a target region after any previous heat treatment), to increase said focused energy output for a subsequent heat treatment in a predetermined manner in response to a lagging electronic signal; or
an electronic control element for directing said heat treatment component, when said heat treatment is repeated (e.g. one or more times—after suitable cooling of a target region after any previous heat treatment), to respectively decrease or increase said focused energy output for a subsequent heat treatment in a predetermined manner in response to a leading or a lagging electronic signal.

The electronic control element may, for example, as the case may be induce the heat treatment component to decrease or increase the energy input to the heat treatment component to effect energy output modification (e.g. modification of heating laser energy output) in response to a leading or a lagging signal as mentioned herein.

In accordance with the present invention heating energy output may, for example, be modified with a view to induce the melt component of said observed signal to at least approach (i.e. be synchronized or be in phase with) the target melt component of said predetermined target signal.

The present invention in accordance with another aspect provides a method for the controlled dopant profile modification of a pre-selected target region (or location) of a semiconductor component by the application of one or more heat treatments to said pre-selected target region (or location), wherein said pre-selected target region (or location) comprises a first region contiguous with a second region, said first region having a heat modifiable dopant profile, said second region having a heat modifiable dopant profile different from said first region,

said method comprising subjecting said pre-selected region (or location) to a heat treatment wherein [e.g. in response to a pre-determined energy input to a heat treatment component comprising a focused heating element,] a focused energy output (e.g. laser energy output) from a heat treat component comprising a focused heating source for providing said focused energy output (e.g. such as a heating element comprising a heating laser),
is directed [i.e. from said heat treatment component] to said pre-selected region (or location) for a pre-determined duration having a start time and a finish time and
is sufficient to melt said pre-selected region (or location) to form a melted region in a melt state

so as to thereby alter the dopant profile of the melted pre-selected target region (or location),

characterized in that said method comprises a probe stage for producing a control signal as a function of a reflected probe signal (e.g. a reflected probe (e.g. optical) signal such as for example a reflected probe laser signal) from said melted region, probe stage comprising:

a) directing a probe (e.g. suitable laser) output signal from a probe signal generating component to said pre-selected region (or location);

b) detecting a reflected probe (e.g. light) signal generated by said probe output signal at said pre-selected region (or location), and converting said reflected probe signal to an observed electronic signal initiated at said start time and comprising a melt component indicative of said melted state,;

c) comparing said observed electronic signal with a predetermined target reflection signal having a target melt component indicative of said melted state, to determine if said observed electronic signal has a respective melt component which is synchronous or asynchronous (i.e. in phase or out of phase) with the target melt component of said predetermined target reflection, and

d) producing at least one control signal selected from the group consisting of a leading signal if the melt component of said observed electronic signal leads the target melt component of said predetermined target reflection signal and a lagging signal if the melt component of said observed electronic signal lags the target melt component of said predetermined target reflection signal.

In accordance with the present invention a method is provided wherein said probe stage is a probe control stage for controlling said heat treatment component as a function of a reflected probe signal from said melted region, wherein said heat treatment is repeated one or more additional times, and wherein, for a subsequent heat treatment, said focused energy output is manipulated or modified in predetermined manner in response to said control signal (i.e. the control signal is derived from a preceding heat treatment).

In accordance with the present invention a method is provided wherein said probe stage produces a leading signal if the melt component of said observed electronic signal leads the target melt component of said predetermined target reflection signal.

In accordance with the present invention a method is provided wherein said probe stage produces a lagging signal if the melt component of said observed electronic signal lags the target melt component of said predetermined target reflection signal.

In accordance with the present invention a method is provided wherein said probe stage produces a leading signal if the melt component of said observed electronic signal leads the target melt component of said predetermined target reflection signal and a lagging signal if the melt component of said observed electronic signal lags the target melt component of said predetermined target reflection signal.

In accordance with the present invention a method is provided wherein said probe stage is a probe control stage for controlling said heat treatment component as a function of a reflected probe signal from said melted region, wherein said heat treatment is repeated one or more additional times (e.g. one or more times—after suitable cooling of a target region after any previous heat treatment), and wherein for a subsequent heat treatment,
said focused energy output is decreased, in predetermined manner, in response to said leading electronic signal;
said focused energy output is increased, in predetermined manner, in response to said lagging electronic signal; or
said focused energy output is respectively decreased or increased, in predetermined manner, in response to said leading electronic signal or said lagging electronic signal.

In accordance with the present invention a method is provided wherein, when said heat treatment is repeated one or more additional times (e.g. to modify the dopant profile by iterative heat applications such as described in the above mentioned U.S. patents), said focused energy output (e.g. laser energy output) is modified (e.g. respectively decreased or increased), for each repeated heat treatment, in response to said leading or lagging electronic signal (as the case may be), so as to induce the melt component of said observed signal to at least approach (i.e. be synchronized or be in phase with) the target melt component of said predetermined target reflection signal.

In accordance with the present invention a method is provided wherein, when said heat treatment is repeated one or more additional times, said focused energy output (e.g. laser energy output) is respectively decreased or increased, for each repeated heat treatment, in response to said leading electronic signal or said lagging electronic signal, so as to induce the target melt component of said observed signal to at least approach (i.e. be synchronized or be in phase with) the target melt component of said predetermined target reflection signal.

It is to be understood herein that the expression “T₀” is a reference to the start time of the application of a focused energy output of a focused heating source to a target region (or location). It is also to be understood herein that the expression T_{F} is a reference to the finish time (i.e. relative to T₀) of the application of a focused energy output of a focused heating source to a target region (or location). In other words, the time period from T₀ to T_{F} represents the duration of the (pulse) time period during which the focused energy source delivers or applies energy to the target region (or location).

It is to be understood herein that the expression ‘observed electronic signal’ is a reference to a signal derived from a detected or observed reflected probe signal and which has as a start time T₀ (as described herein). It also to be understood herein that the expression ‘observed electronic signal’ is a reference to a composite signal comprising a first (or initial) signal component indicative of a solid state of the target region and a subsequent second signal component indicative of a melted state of the target region, the second signal component comprising a melt component as described herein indicative of the melt state.

In any case it is to be understood herein that the expression ‘melt component’ relates to the subsequent second signal component of an observed (i.e. detected) electronic signal or of a predetermined target reflection signal (see, for example FIG. 9 discussed below). In other words, the second signal component, as mentioned above, comprises a ‘melt component’ (as described herein). Thus it is to be understood herein that the expression ‘melt component’ has a value, (i.e. signal value or derivative of a signal value) at a predetermined, given or observed time value (i.e. at a specific time or over a specific time period) after To. Thus, it is to be understood herein that any reference herein to a comparison of a ‘melt component’ of an observed (i.e. detected) electronic signal with a “melt component’ of a predetermined target reflection signal is a “timing” comparison of the same type of ‘melt component’ value occurring after T₀. In other words, the comparison is made to determine if the same type of ‘melt component’ occurs at the same or a different time value T in relation to (i.e. after) T₀. A melt component of same type may, for example, be a signal value indicative of a change in slope (i.e. an upward change of slope of an observed or target reflection signal indicative of the start of melting at a time value T).

Thus as may be appreciated if a timing comparison indicates that the ‘melt component’ of an observed (i.e. detected) electronic signal occurs at a time T_{H} which is before the time T_{T} of the “melt component’ of a predetermined target reflection signal (see FIG. 11 below) then the ‘melt component’ of an observed (i.e. detected) electronic signal is understood herein to “lead” the “melt component’ of a predetermined target reflection signal. In this case in accordance with the present invention a leading electronic signal (e.g. a signal having a numeric value which is positive) may be produced by the electronic signal analyzer element, i.e. a “leading” signal being indicative to a focused heating source that the energy of the focused energy source is for example to be lowered (e.g. by a predetermined % amount, e.g. by 5%). Furthermore, it is of course to be understood herein that for a melt component of an observed electronic signal to be acceptable, it may but need not necessarily coincide exactly with the melt component of the predetermined target reflection signal. Thus, as desired or necessary, a leading signal may, for example, be generated only in cases wherein the melt component of an observed electronic signal is outside or prior to a predetermined specified tolerance (e.g. having a time value less than a time limit which is for example 1%, 5%, 10% ,etc. or other desired time value less than the time T_{T}) of the melt component of the predetermined target reflection signal; e.g. a leading signal may be generated only when the timing of the melt component of the observed electronic signal is prior to an acceptable lower time limit value (e.g. a leading signal may be generated if the observed time value is less than 90% of the time T_{T} but not if it is 95% of the time T_{T}, i.e. a leading signal may be generated if the observed time value is less than 0.9×T_{T}).

On the other hand, as may also be appreciated if a timing comparison indicates that the ‘melt component’ of an observed (i.e. detected) electronic signal occurs at a time T_{L} which is after the time T_{T} of the “melt component’ of a predetermined target reflection signal (see FIG. 11 below) then the ‘melt component’ of an observed (i.e. detected) electronic signal is understood herein to “lag” the “melt component’ of a predetermined target reflection signal. In this case in accordance with the present invention a lagging electronic signal (e.g. a signal having a numeric value which is negative) may be produced by the electronic signal analyzer element, i.e. a “lagging” signal being indicative to a focused heating source that the energy of the focused energy source is for example to be raised (e.g. by a predetermined % amount, e.g. by 5%). As mentioned, it is of course to be understood herein that for a melt component of an observed electronic signal to be acceptable, it may but need not necessarily coincide exactly with the melt component of the predetermined target reflection signal. Thus, as desired or necessary a lagging signal may, for example, be generated only in cases wherein the melt component of an observed electronic signal is outside or beyond a predetermined specified tolerance (e.g. having a time value beyond a time limit which is for example 1%, 5%, 10%, etc. or other desired time value greater than the time T_{T}) of the melt component of the predetermined target reflection signal; e.g. a lagging signal may be generated only when the timing of the melt component of the observed electronic signal is later than an acceptable upper time limit value (e.g. a lagging signal may be generated if the observed time value is 10% greater than the time T_{T}, but not if it is 5% greater than the time T_{T} i.e. a lagging signal may be generated if the observed time value is greater than 1.1×T_{T}).

Furthermore, as may be appreciated if a timing comparison indicates that the ‘melt component’ of an observed (i.e. detected) electronic signal occurs at a time T_{S} which is the same as the time T_{T} of the “melt component’ of a predetermined target reflection signal (see FIG. 11 below) then the ‘melt component’ of an observed (i.e. detected) electronic signal is understood herein to be synchronous or coordinated with the “melt component’ of a predetermined target reflection signal. In this case in accordance with the present invention no further electronic signal may be need to be generated or if so desired or necessary an “in sync” or NUL electronic signal (e.g. a signal having a value which is zero) may be produced by the electronic signal analyzer element, i.e. an “in sync” signal being indicative to a focused heating source that the energy of the focused energy source is for example at a desired or necessary value. On the other hand, it is not necessary to have a NUL signal indicative of an acceptable focused energy output from a focused energy source. For example a system (or a method) in accordance with the present invention may be configured such that any repeated heat treatment may use the previous energy output settings as default settings in the absence of any suitable signal indicating that the energy output of the focuses energy source is to be changed from the default settings. As mentioned above, it is of course to be understood herein that for a melt component of an observed electronic signal to be acceptable, it may but need not necessarily coincide exactly with the melt component of the predetermined target reflection signal. As desired or necessary a NUL signal (or for that matter no signal at all) may be generated in cases wherein the melt component of an observed electronic signal is within a predetermined specified tolerance of the melt component of the predetermined target reflection signal, i.e. no signal or as desired a NUL signal may be generated if the timing value of the melt component of the observed electronic signal is within a desired range (e.g. within ±10% of the time T_{T}) of that of the melt component of the predetermined target reflection signal.

Thus it is further to be understood herein that a melt component may, for example, have a type of value which is a discrete value at a time between T₀ and T_{F} wherein T₀ and T_{F} are as defined above. A melt component may further have a type of value which may, for example, comprise a plurality of such discrete values; the melt component may, for example, have a type of value which comprises a plurality of discrete values which are continuous (i.e. represent a curve); the melt component may, for example, have a value derived from such a curve of discrete values (i.e. derivative value, i.e. tangent), etc.

Thus it is to be understood herein that the expressions ‘synchronous or asynchronous”, ‘in phase or out of phase’, or the like when used in relation to a comparison of the observed electronic signal or part thereof (e.g. a melt signal component of said observed electronic signal) with a predetermined target reflection signal or part thereof (e.g. the target melt signal component of said predetermined target reflection signal) characterize such determination as being a timing determination of whether the signals or parts thereof have the same or different value(s) occurring at the same or different time(s) relative to T₀. In other words these expressions relate to a temporal evaluation, namely the determination of whether or not (temporal) values is/are either before [i.e. leading in time], after [i.e. lagging in time] or in [time] “sync” with a predetermined temporal value.

The heat treatment component including the focused heating source may take any suitable (known) form such as for example as set forth in the above mentioned U.S. Pat. Nos. 6,329,272, 6,890,802 and 7,217,986.

It is to be understood herein that the probe output signal may be produced and applied in any suitable (known) manner keeping in mind the purpose thereof as described herein. The probe output signal may be applied to the target region in a continuous fashion or if so desired in a discontinuous fashion (i.e. pulse). If the probe signal is applied in a discontinuous fashion it may be applied over the same time period as the energy output from the focused heating source; i.e. the probe signal may be initiated ( at T₀) and terminated (at T_{F}) in unison with the energy output from the focused heating source.

Keeping the above in mind, the probe (i.e. optical or light) signal generating component may take on any known form; see for example (known) He—Ne laser type systems. The probe generating component may for example take a form such as set forth for example in FIG. 13 herein.

The probe signal detector element may also take on any suitable (known) form, such as a photodetector such as for example a silicon PIN photodetector for an He—Ne laser.

The electronic signal analyzer as well as any electronic control element for directing the heat treatment component may take on any suitable form and may comprise known types of computer components such as a CPU, memory unit, I/O unit, etc. The electronic signal analyzer as well as any electronic control element may be driven by any suitable computer type programme(s) or software(s) suitably configured to achieve the purposes described herein.

In accordance with the present invention a predetermined target reflection signal may for example be obtained empirically by submitting one or more like semiconductor components to heat treatments as set forth in the above mentioned U.S. patents so as to obtain trimmed semiconductor components which are acceptable in relation to the applied power or energy output of the focused energy source. The determination of the target reflection signal may, for example, be carried out in conjunction with the above heat treatments i.e. reflection measurements may be made using a system such as described herein in order to obtain the desired predetermined target reflection signal for use herein (e.g. to obtain an average target signal value).

### BRIEF DESCRIPTION OF THE DRAWINGS

The present invention will be described below with reference to the drawings which illustrate the invention by way of example only. The invention will in particular be described by way of example only in relation to a semiconductor configuration exploiting layers such as interdielectric and passivation layers. It is to be understood that the invention may be exploited in relation to semiconductor components which do not have such layers, keeping in mind of course that the semiconductor component must nevertheless be susceptible to dopant profile change by the application of heat such as described herein. The invention will be described with respect to the drawings in relation to an example configuration(s) which allows for the exploitation of both leading and lagging signals. It is of course to be understood as mentioned above that the system and/or method of the invention may as desired or necessary only exploit either the leading signal or the lagging signal. For example a leading signal only may be exploited if it is desired to only avoid too high focused energy outputs. Thus in the figures:

FIG. 1 schematically illustrates a cross-sectional view of an example trimmable or tunable (integrated) semiconductor component or device;

FIG. 2 illustrates a cross-sectional view of the tunable (integrated) semiconductor component or device as shown in FIG. 1, wherein on application of a heating (laser) pulse, a portion of the tunable integrated semiconductor device is shown to be melted;

FIG. 3 schematically illustrates a cross-sectional view of a further example trimmable or tunable (integrated) semiconductor component or device having a plurality of interdielectric or passivation layers wherein on application of an underpowered heating (laser) pulse, an insufficient portion of the tunable integrated semiconductor device is shown to be melted;

FIG. 4 schematically illustrates a cross-sectional view of a further example trimmable or tunable (integrated) semiconductor component or device having a plurality of interdielectric or passivation layers wherein on application of a heating (laser) pulse having a target (i.e. desirable) power (i.e. energy), a suitable portion of the tunable integrated semiconductor device is shown to be melted;

FIG. 5 schematically illustrates a cross-sectional view of a further example trimmable or tunable (integrated) semiconductor component or device having a plurality of interdielectric or passivation layers wherein on application of an overpowered heating (laser) pulse, an undesirable too great portion of the tunable integrated semiconductor device is shown to be melted;

FIG. 6 illustrates a cross-sectional view of the tunable (integrated) semiconductor component or device as shown in FIG. 1, wherein a probe signal is directed to the target region and a reflected probe signal is generated thereby indicative of the solid state of the target region;

FIG. 7 illustrates a cross-sectional view of the tunable (integrated) semiconductor component or device as shown in FIG. 6, wherein on application of the heating (laser) pulse, a portion of the tunable integrated semiconductor device is shown to be melted and wherein a probe signal is directed to the target region and a reflected probe signal (i.e. of increased signal strength) is generated thereby indicative of the melt state of the target region;

FIG. 8 illustrates a schematic graphic representation of an example laser heating pulse in the shape of a triangle (i.e. saw tooth) as applicable against the semiconductor component or device as shown in FIG. 7, the saw tooth pulse having a start time T₀ and a finish time T_{F};

FIG. 9 illustrates a graphic representation of an example observed electronic signal initiated at the start time (T₀) of the saw tooth laser pulse of FIG. 8, the observed electronic signal being a composite signal comprising a first (or initial) signal component indicative of a solid state of the target region and a subsequent second signal component indicative of a melted state of the target region, the second signal component comprising a melt component as described herein;

FIG. 10 illustrates a graphic representation of a further example measured or observed, target reflection signal curve associated with two other further example observed (reflection) signal curves representative of the cases wherein the heating laser energy output is either too high or too low as compared to the target reflection curve;

FIG. 11 illustrates in a schematic graphic representation (in partial form) the curves of FIG. 10, namely, target reflection signal curve 46 and the other reflection signal curves 44 and 48 representative of the cases wherein the focused energy output (e.g. laser energy output) is either too low or too high;

FIG. 12 illustrates in block format an example system in accordance with the present invention for the control of the heat treatment component as a function of a signal reflected from the target region;

FIG. 13 illustrates a schematic representation of an example in-situ probe signal generating component for generating a reflected probe signal from the target region of a semiconductor component, the in-situ probe system being associated or integrated with a system for applying a focused heat source (e.g. heating laser) at the target region;

FIG. 14 illustrates an example algorithm for in-situ (iterative) control of the heating laser energy output as a function of the reflected probe signal generated by the probe signal at the target region of the semiconductor component or device, i.e. as a function of the derived observed electronic signal;

FIG. 15 illustrates a schematic graphic representation of example laser heating pulses for modifying the laser energy output of the heating laser as applicable against the semiconductor component or device as shown in FIG. 7, wherein the laser output pulses are each in the shape of a triangle (i.e. saw tooth), the saw tooth pulses having a start time T₀ and a finish time T_{F} but wherein the maximum laser energy output of each pulse is different;

FIG. 16 illustrates an example graphic representation of heating laser energy (i.e. power) output as a function of pulse number during an iterative control of the heating laser output (watts); and

FIG. 17 illustrates example measured times (T) to initiate melting (i.e. time elapsing (seconds) from T₀ to a slope change indicative of melting) as a function of pulse number during an iterative control of the heating laser output; this figure is complementary to FIG. 16.

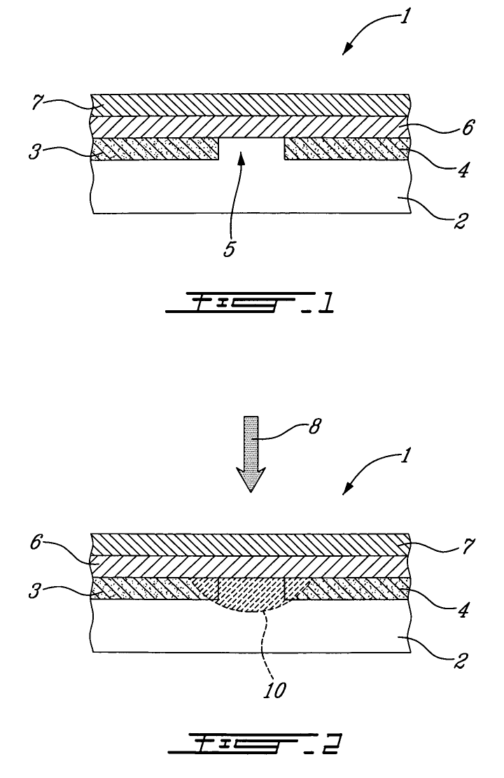

The above mentioned U.S. Pat. Nos. 6,329,272, 6,890,802 and 7,217,986 illustrate various example semiconductor components or devices which may be exploited in the context of the present invention. For the purposes of illustration only, FIG. 1 illustrates a cross-sectional view of an example (integrated) semiconductor component or device 1 tunable or trimmable in accordance with an embodiment of the present invention; please see U.S. Pat. No. 6,329,272 for more specific details. The tunable (integrated) semiconductor component or device 1 as shown may comprise various layers (i.e. a plurality of layers).

Thus, for example, semiconductor component or device 1 may comprise a substrate 2. The substrate 2 may comprise semiconductor materials such as silicon, germanium, gallium arsenide, silicon-germanium or other suitable semiconductor materials.

The example tunable (integrated) semiconductor device 1 illustrated in FIG. 1 is also shown as comprising a doped layer defining a first region having a heat modifiable dopant profile. This first region comprises two heavily doped sub-regions, namely heavily doped sub-regions 3 and 4; a semiconductor device could of course comprise more than two of such heavily doped sub-regions. As may be understood, heavily doped sub-regions 3 and 4 may be doped with either n or p type dopants in sufficient concentrations to provide sub-regions of a required or desired dopant profile (i.e. dopant concentrations) such that said heavily doped regions 3 and 4 may be electrically conductive. For example, the dopants may be phosphorous, and may be of a concentration of the order of between 10¹⁶ to 10²⁰ atoms per cm³. The thickness of the heavily doped sub-regions may for example be of 0.25 micrometers, but may be greater or lesser in accordance with the requirements of a given manufacturing process. Furthermore, the configuration and disposition of the heavily doped regions may also be in accordance with the requirements of a given manufacturing process; please see the above mentioned U.S. patents for more specific details.

The example tunable (integrated) semiconductor component or device 1 illustrated in FIG. 1 is also shown as comprising a lightly doped region 5 which is disposed intermediate the heavily doped sub-regions 3 and 4. The lightly doped region 5 may be doped with the same dopant as the heavily doped sub-regions 3 and 4, or alternatively, may comprise a different dopant than that present in the adjacent heavily doped sub-regions 3 and 4. As shown the lightly doped region 5 is disposed to be adjacent to and abutting heavily doped sub-regions 3 and 4 (i.e. contiguous with sub-regions 3 and 4). The type and concentration level of dopants in lightly doped region 5 may be such that, prior to tuning or trimming, no electrical current may flow between heavily doped sub-regions 3 and 4 across region 5, i.e. the initial resistance of lightly doped region 5 is high enough to prevent or inhibit (most if not all) electrical current to flow between heavily doped regions 3 and 4. As may be understood, from the above mentioned U.S. patents (known) heat trimming or tuning may be used to modify ( i.e. lower or raise) the impedance (e.g. resistance) of lightly doped region 5 as required.

The (integrated) semiconductor component or device 1 is further shown as comprising an oxide layer 6, such as silicon dioxide (SiO₂). The (integrated) semiconductor component or device 1 is also shown as comprising a passivation layer 7, such as silicon nitride (Si₃N₄). These are known type of layers. The layers 6 and 7 are of course in any event selected so as to be more or less transparent to the focused heating source (e.g. a laser heat source) so as to allow a focused heating source, for trimming or tuning purposes, to apply heat to a target region comprising region 5 and parts of sub-regions 3 and 4 contiguous with region 5.

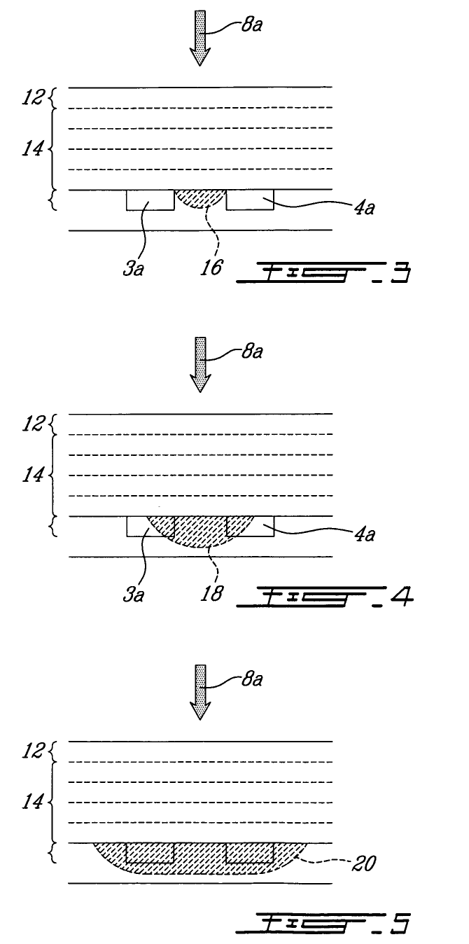

Turning to FIG. 2, this figure illustrates a melting stage of a trimming process involving the semiconductor component or device 1 of FIG. 1. As may be understood (from the above mentioned U.S. patents), a focused heating source (not shown) is disposed above the semiconductor component or device 1 and is directing a heating pulse 8 to the above mentioned target region; again for further trimming details please see the above mentioned U.S. patents. At the process stage indicated in FIG. 2 the heating pulse 8 has passed through the layers 6 and 7 and has induced the target region to pass from a solid to a melt state; the melted region being designated by the reference numeral 10. As may be seen the melted region 10 comprises region 5 and parts of sub-regions 3 and 4 contiguous with region 5.

As mentioned above, a practical difficulty may be encountered with respect to the delivery of energy to the target region of a semiconductor component when trimming a plurality of semiconductors components which are nominally supposed to be the same. A process for the production of a plurality of like semiconductor components, which are subsequently to be subjected to (known) trimming technique, may produce semiconductor components which although nominally the same, may nevertheless have (minute) differences. For example, there may be differences with respect to (layer) composition and/or thickness, e.g. interdielectric layers or passivation layers may have variable thicknesses and even composition. Such variations with respect to (layer) composition and thickness, may, for example, lead to heating laser beam reflection and/or interference. Thus, notwithstanding that the energy output from a focused heating source may be maintained at a constant level when trimming a plurality of the same semiconductor components, such reflection and/or interference may significantly alter (e.g. decrease or even increase) the energy output from the focused heating source which is actually applied to the heat modifiable target region of any given semiconductor component.

The difficulty with respect to the control of the actual deliverable energy to a heat modifiable target region of any given semiconductor component is further illustrated in schematic form in FIGS. 3, 4 and 5. For each of these figures the heating pulse from the focused heating source has the same energy or power (Pₒ) and in each case is generally designated by the arrows having the same reference numeral 8a. Prior to the application of a heat treatment, the semiconductor components in FIGS. 3, 4 and 5 nominally have the same features, namely a passivation layer 12, additional interdielectric layers 14, as well heavily doped sub-regions 3a and 4a; the sub-regions 3a and 4a are contiguous with and spaced apart by an intermediate lightly doped region (see FIG. 1).

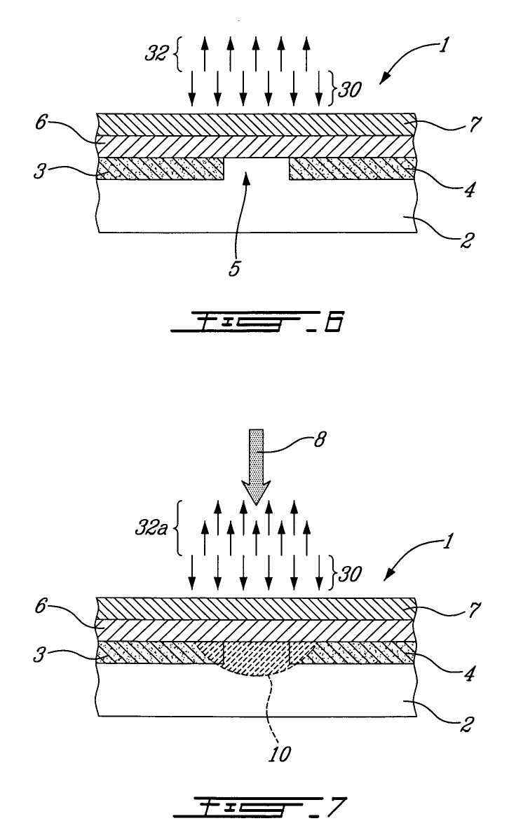

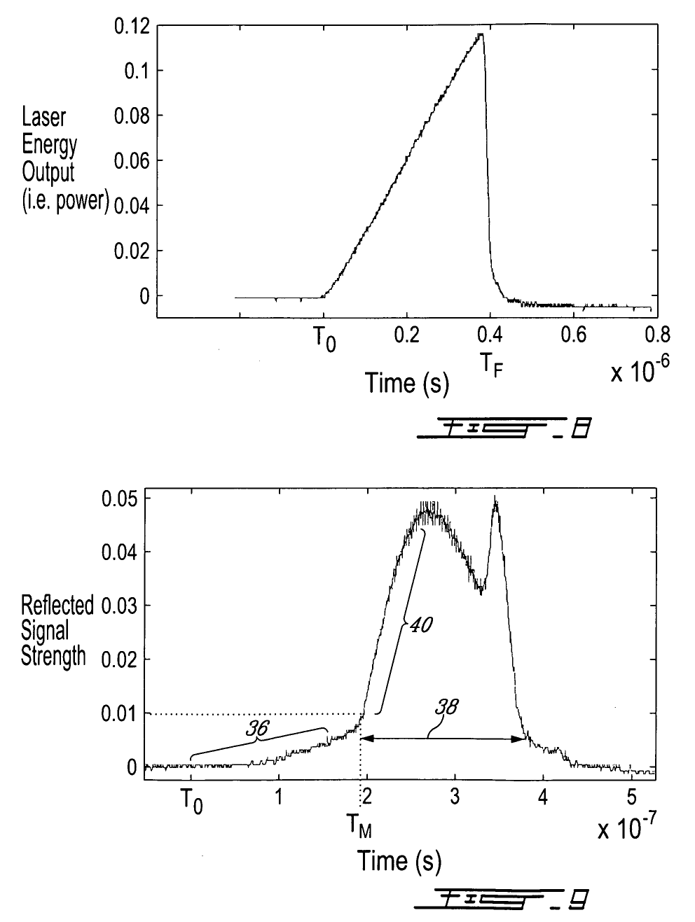

On the other hand, for the purposes of illustration, the semiconductors in each of FIGS. 3, 4 and 5 have different energy transmission coefficients (i.e. for the portion thereof comprising layers 12 and 14). The energy transmission coefficient ( herein sometimes referred to as K) is to be understood herein as being the ratio of the energy actually transmitted to the target region to the energy initially incident on the layer 12; i.e. if there is no or little interference or absorption K may be (substantially or close to) 1 but if there is substantial interference or absorption K may for example be smaller than 1, in other words K may not be greater than 1. For illustration purposes herein the semiconductor component of FIG. 3 has an energy transmission coefficient K₃; the semiconductor component of FIG. 4 has an energy transmission coefficient K₄; and the semiconductor component of FIG. 5 has an energy transmission coefficient K₅. Furthermore the values of the energy transmission coefficients for the semiconductor components of FIGS. 3, 4 and 5 have the following relative relationship: K₃<K₄<K₅ (e.g. K₃=0.6; K₄=0.8; K₅=0.95).

For the purposes of FIGS. 3, 4 and 5 the power (Pₜ) actually delivered to the target region may be represented respectively as follows; for FIG. 3, Pₜ=K₃×Pₒ; for FIG. 4, Pₜ=K₄×Pₒ; and for FIG. 5, Pₜ=K₅×Pₒ.

As may be appreciated from the FIG. 3, the power (Pₜ) actually delivered to the target region for FIG. 3 is shown as being too low since the melted region 16 comprises only the intermediate region between sub-regions 3a and 4a. As may be appreciated from the FIG. 4, the power (Pₜ) actually delivered to the target region for FIG. 4 is shown as being just right since the melted region 18 comprises not only the intermediate region between sub-regions 3a and 4a but also portions of sub-regions 3a and 4a. As may be appreciated from the FIG. 5, the power (Pₜ) actually delivered to the target region for FIG. 5 is shown as being too high since the melted region 20 comprises not only the sub-regions 3a and 4a, the intermediate region between sub-regions 3a and 4a but also regions beyond sub-regions 3a and 4a. Accordingly, as may be seen although the initial power input to the semiconductor components is the same the fact that the energy transmission coefficients are different leads to different results.

The present invention contemplates a solution to the above problem whereby the energy output of a focused heating source may be adjusted or modified as a function of in situ (optical) probe signal measurement (s) which may be taken in real time.

Turning to FIGS. 6 to 9, these figures illustrate in general fashion the focused heating source control mechanism of the present invention wherein a probe output signal is applied (by way of example only) continuously to the target region.

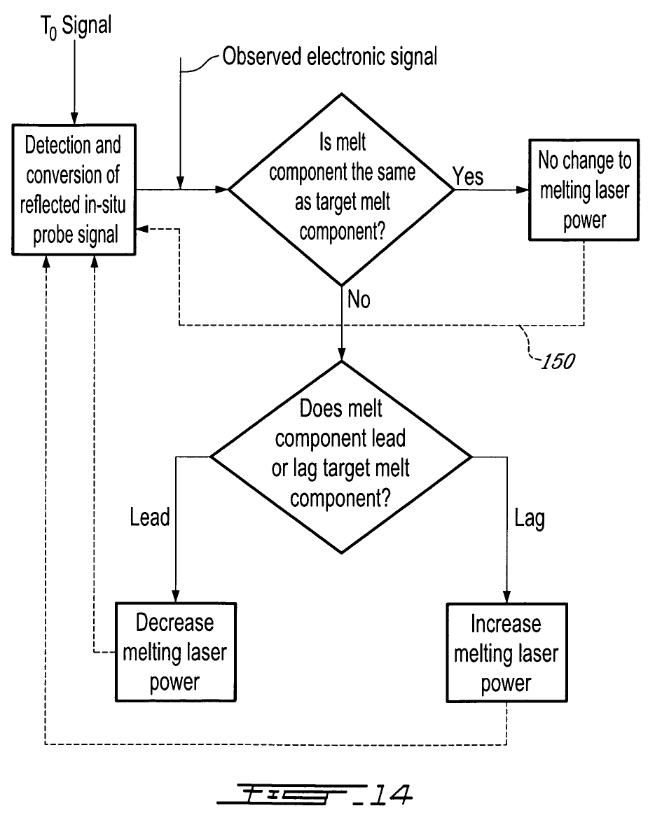

Referring to FIG. 6, this figure shows the semiconductor component of FIG. 1 which is associated with a probe (i.e. optical or light) signal generating component (not shown). The probe signal generating component is disposed above the semiconductor component or device 1 and is suitably configured for directing a probe output signal (e.g. laser probe output signal) to a pre-selected target region (or location) of the semiconductor component or device 1 (of FIG. 1). An example probe signal generating system integrated with a focused heating source is illustrated in FIG. 13 which shall be discussed below. At the process stage indicated in FIG. 6, a focused heating source is not directing a heating pulse 8 (see FIG. 2) to the above mentioned target region such that the target region is in a solid state. On the other hand, the probe signal generating component is directing a probe output signal 30 (e.g. laser probe signal) to the above mentioned solid state target region. The probe output signal 30 falling on the solid state target region generates a reflected probe signal 32 which can be picked up by a suitable (known) detection mechanism and converted (in any known manner) into a (suitable) signal indicative of such solid state.

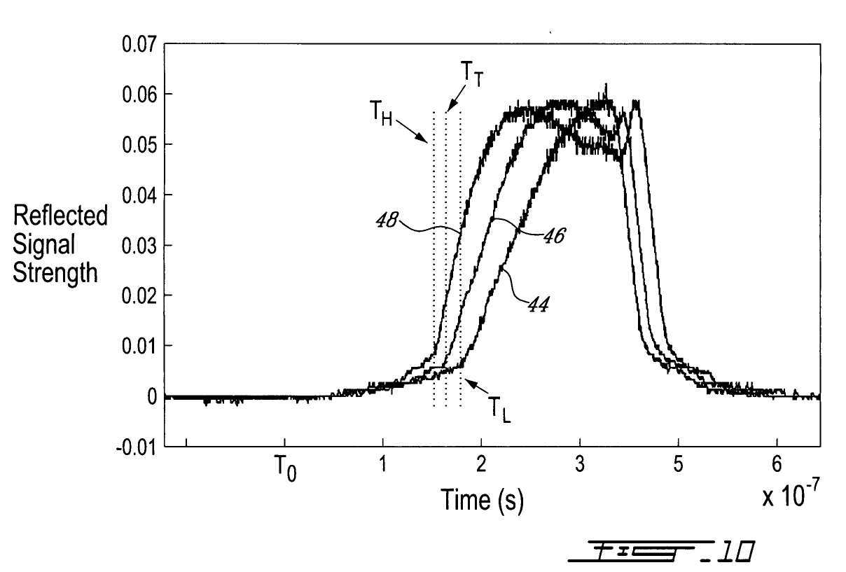

Referring to FIG. 7, this figure adds to FIG. 6, a heating pulse 8 as discussed with respect to FIG. 2. In other words a focused heating source is now directing a heating pulse 8 (see FIG. 2) to the above mentioned target region to produce the above mentioned melted region designated (also in FIG. 7) by the reference numeral 10. On the other hand, the probe signal generating component is likewise directing a probe output signal 30 (e.g. laser probe signal) to the above mentioned solid state target region. The probe output signal 30 falling on the melted region 10 generates a reflected probe signal 32a of greater intensity than the reflected probe signal 32 (of FIG. 6) which can likewise be picked up by a suitable (known) electronic detection mechanism and converted (in any known manner) into a signal indicative of such solid state.

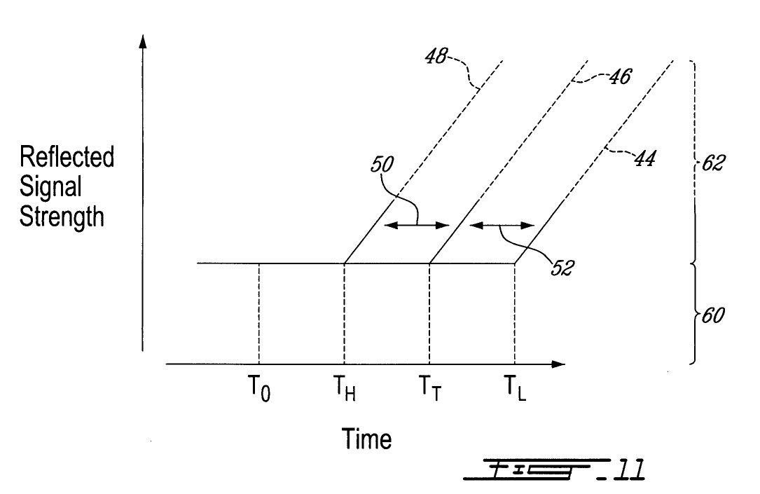

Referring to FIGS. 8 and 9, FIG. 8 illustrates a laser heating pulse in the form of a saw tooth whereas FIG. 9 illustrates an observed electronic signal (i.e. the electronic signal shown in FIG. 9 is identified as a reflected signal).

For illustration purposes the saw tooth laser pulse of FIG. 8 may be considered as the beam 8 of FIG. 7. Although the heating pulse of FIG. 8 is shown for illustration purposes to be a single pulse it is to be understood herein that a heating pulse may be one continuous pulse or be composed of a plurality of smaller pulses; see the above mentioned U.S. patents.

As may be seen from FIG. 8 the saw tooth beam initiates at time T₀ and terminates as time T_{F}. For illustration purposes, one may consider the reflected signal curve as shown in FIG. 9 to be an ‘observed electronic signal” derived from the probe output signal 30 (of FIGS. 6 and 7) also initiated (e.g. recording in electronic memory initiated as of ) at time T₀ (of FIG. 8) and terminating at some undesignated predetermined time keeping in mind the purposes herein; if desired for example the recording (i.e. in electronic memory) of the reflected signal may terminate at or just after T_{F}. In any event, the length of time of the recording of the reflected signal (i.e. after T₀) is of course to be long enough to generate an ‘observed electronic signal” as understood herein. Thus also for illustration purposes, one may consider the reflected signal curve as shown in FIG. 9 to be a composite signal comprising a first (or initial) signal component (designated by the reference number 36) and a subsequent second signal component (designated by the reference number 38). The first (or initial) signal component 36 may be considered to be derived from reflected probe signal 32 (of FIG. 6) and the subsequent second signal component 38 may be considered to be derived from reflected probe signal 32a (of FIG. 7). The first (or initial) signal component 36 may be considered to be indicative of the solid state of the target region and the subsequent second signal component 38 may be considered to be indicative of a melted state of the target region. The second signal component 38 comprises a signal portion 40 which may be considered to comprise various melt components of the second signal including the change in slope at time T_{M}.

Such in situ probe (e.g. optical) signal measurement(s) as described above in relation to FIGS. 6 to 9 may used to modify or adjust (as necessary) the energy output of the focused heating source (i.e. modify the irradiation beam power) in order to obtain a desired predetermined reflective probe measurement indicative of a desired or necessary focused energy output from the focused heating source.

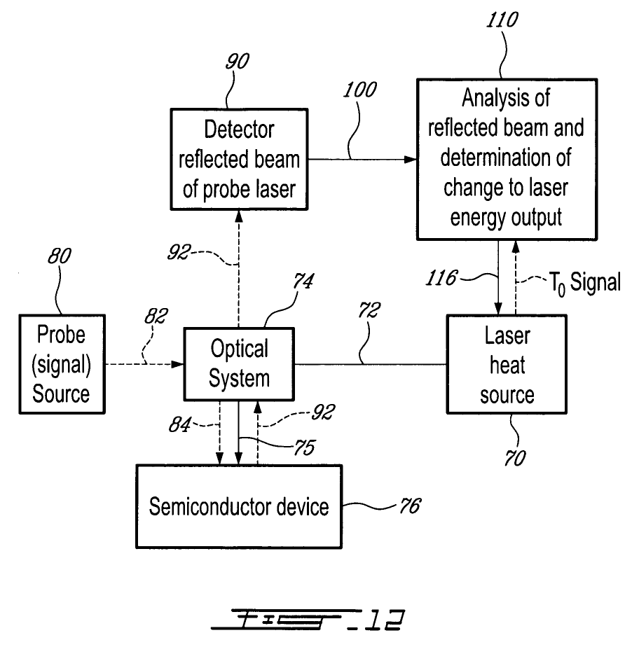

Referring to FIG. 10, this figure is illustrative of the type of probe measurements that may be obtained in relation to heat treatments as set forth in FIGS. 3, 4 and 5 using the probe signal technique described in relation to FIGS. 6 and 7 as well as a saw tooth type focused energy output from a focused heating source (i.e. a laser heating source).

The reflected signal curve which may be attributable to the heat treatment stage set forth in FIG. 3 may be the curve 44 in FIG. 10. The reflected signal curve which may be attributable to the heat treatment stage set forth in FIG. 4 may be the curve 46 in FIG. 10. The reflected signal curve which may be attributable to the heat treatment stage set forth in FIG. 5 may be the curve 48 in FIG. 10. As may be seen there is respective changes in slope for curves 44, 46 and 48 at respective times T_{L}, T_{T} and T_{H} relative to T₀; the change in slope is indicative of a change in state from solid to liquid (i.e. from a solid to a melt state) at times T_{L}, T_{T} and T_{H}.

In light of the previous comments with respect to FIGS. 3, 4 and 5 in relation to the input energy P₀, it may be appreciated that curve 46 (with melt time T_{T}) may be considered to be a desirable target curve in view of the satisfactory nature of the melt region 18; in other words P₀ is an appropriate energy for the focused heating source to apply to the semiconductor component of FIG. 4. On the other hand, curve 48 with a time T_{H} which leads the time T_{T} and reflects the unsatisfactory melt region 20 is indicative that P₀ is not an appropriate energy for the focused heating source to apply to the semiconductor component of FIG. 5. In the case of curve 48 there is an indication that P₀ provides too much energy to the target region and energy input should therefore be reduced. Furthermore, curve 44 with a time T_{L} which lags the time T_{T} and also reflects the unsatisfactory melt region 16 is indicative that P₀ is also not an appropriate energy for the focused heating source to apply to the semiconductor component of FIG. 3. In the case of curve 44 there is an indication that P₀ provides too little energy to the target region and should therefore be increased.

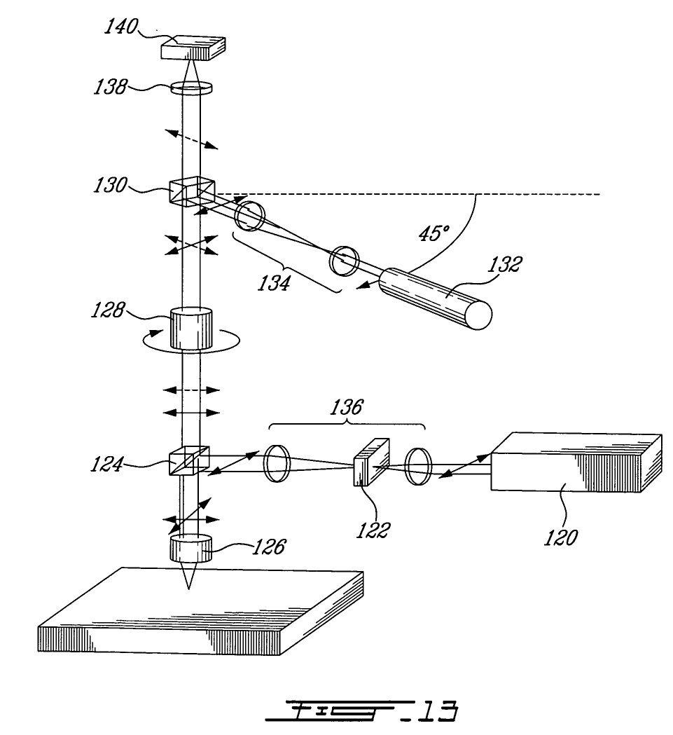

FIG. 11 also shows the leading feature of curve 48; see the leading double headed arrow 50. This figure also shows the lagging feature of curve 44; see the leading double headed arrow 52. As also may be appreciated from FIG. 11 each of the reflected signal curves 44, 46 and 48 (i.e. observed electronic signals) is a composite signal comprising a signal component 60 indicative of solid state and a signal component 62 indicative of melt state. As may be appreciated a melt component of the curve 46 (e.g. the time T_{T} and the related slope change characteristic of curve 46 at this time) may be loaded into an electronic memory unit of a suitably programmed computer analyzer component as a target reference for comparison with comparable melt components of other reflected signals obtained when heat trimming further semiconductor components of the same kind and for the same purpose. The desired reference or target melt component may alternatively be obtained from measurements of made on a large number of samples of like semiconductor devices and an average target melt component value determined for use as a reference.

FIG. 12 illustrates in block format an example system in accordance with the present invention for the control of the heat treatment component as a function of a probe signal reflected from the target region; the system may be integrated or incorporated into known trimming systems such as those as described in the above mentioned U.S. patents. For example, the example system may be integrated into a laser system shown in FIGS. 11 and 12 of U.S. Pat. No. 6,329,272, i.e. for the modification of the dopant profile of a target region of a semiconductor component.

The example system illustrated in FIG. 12 comprises a laser heat source 70 (i.e. a focused heating source). The laser heat source 70 generates a heating laser output 72 (e.g. pulse(s)) which is/are directed to an optical system 74 which directs a laser heat energy output 75 (e.g. pulse(s)) to the target region of a semiconductor component 76. The system also has a probe signal generator 80 for generating an output signal 82 which is also directed to an optical system 74 which directs a probe output signal 84 (e.g. continuous signal or a pulsed signal) to the target region of a semiconductor component 76. The system further has a detector 90 for detecting a reflected probe signal 92 from the semiconductor component 76, the reflected probe signal passing through the optical system 74. The detector 90 on receiving the reflected probe signal 92 provides an electronic signal output 100 which reflects the incoming probe signal 92. The signal output 100 is delivered to an analyzer/control unit 110. The analyzer/control unit 110 may include computer elements which may be configured in any (suitable) manner so as to achieve the purposes set forth herein. The analyzer/control unit 110 may comprise a (digital) memory element for storing a predetermined target reflection signal having a target melt component indicative of said melted state. The analyzer/control unit 110 may be configured in any (suitable) way to provide a power control signal 116 to the laser heat source 70 for directing the laser heat source 70 to maintain the laser power output level, decrease the laser output level or increase the laser output level in any desired manner as long as the desired energy control is achieved. The analyzer/control unit 110 may comprise a pulse generator functionality for controlling the laser heat pulses. The analyzer/control unit 110 may comprise its own timer for setting T₀ or may receive a T₀ signal from laser heat source 70. The example system of FIG. 12 as may be appreciated may be used to modify the dopant profile of a semiconductor component by appropriate configuration of the control elements for this purpose; i.e. to reflect the procedures set forth in the above mentioned U.S. patent applications.

The example system shown in FIG. 12 may be formed from any suitable materials, electrical components, optical components etc. As may be appreciated, the illustrated optical system 74 should be able to separate the trajectory of the laser probe signals and the laser heating output so that their intensities may be measured separately before and after the interaction with the semi-conductor device. The system elements 70, 74 80 and 82 for in-situ generation of the probe signal along with the other heating laser output as well as the probe signal detector may be formed from known components and may be arranged as a group in a known manner such as set forth in FIG. 13. In the example set-up shown in FIG. 13 the probe and heat laser outputs as may be appreciated are coterminous or co-linear. If desired, however, any other suitable or analogous set-up may be used keeping in mind the purpose thereof as described herein; see for example Shaochen, Chen et al., Photothermal displacement detection and transient imaging of bump growth dynamics in laser zone texturing of Ni—P disk substrates, Journal of Applied Physics, Vol. 85, No. 8, 15 Apr. 1999, p. 5618; Shaochen, Chen et al., Noncontact nanosecond-time-resolution temperature measurement in excimer laser heating of Ni—P disk substrates, Applied Physics Letters, Vol. 71, No. 22, 1 Dec. 1997, p. 3191; and Shaochen, Chen et al., Photothermal displacement mesurement of transient melting and surface deformation during pulsed laser heating, Applied Physics Letters, Vol. 73, No. 15, 12 Oct. 1998, P. 2093.

Thus FIG. 13 shows the following:
an Nd:YAG laser 120 (for heating) emitting at 532 nm;
an acousto-optic modulator 122;
a beam splitter 124;
a microscopic objective 126;
a 45° Faraday rotator 128;
abeam splitter 130;
a HeNe probe laser 132;
beam expanders 134 and 136;
lens+filter 138; and
photodetector 140.

This probing optical source (HeNe probe laser 132) should have a sufficiently low energy to prevent or inhibit any significant heating of the semiconductor device. The probe source may as mentioned above provide a continuous probe signal or a pulsed probe signal; but if it is pulsed, the pulse width should be at least as long as the main laser heating source. The wavelength of the probe signal is advantageously different from that of the main focused heating source since this will allow the two beams to be more effectively separated and analyzed.

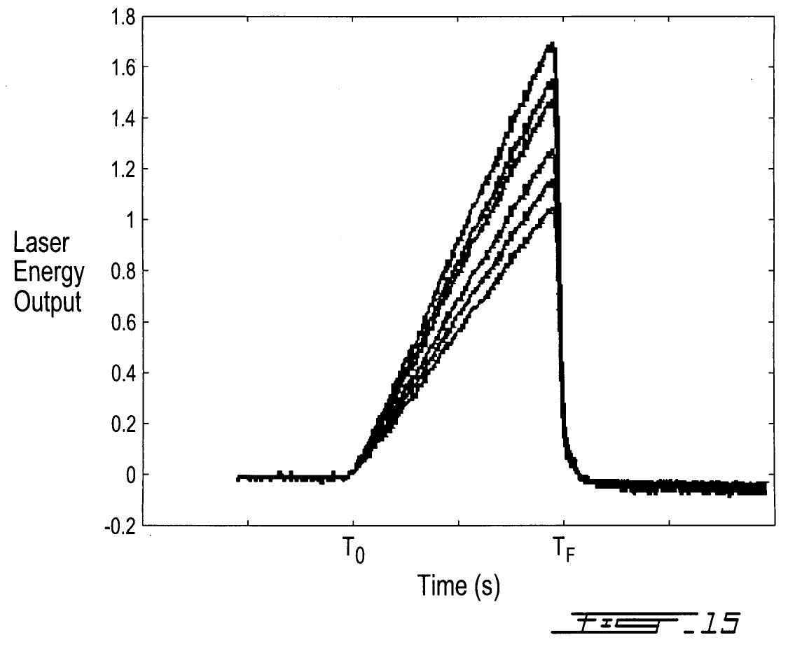

FIG. 14 illustrates an example algorithm for in-situ (iterative) control of the heating laser energy output as a function of the reflected signal generated by the probe signal at the target region of a semiconductor component or device. The dotted lines are generally indicative of the connection between the stage wherein there is manipulation of focused energy output from the heating laser and the detection of the reflected probe signal which gives rise to the “observed electronic signal”, followed by the rest of the loop analysis. As mentioned above, it is not necessary to have a NUL signal indicative of an acceptable focused energy output from a focused energy source. A system in accordance with the present invention may be configured such that any repeated heat treatment may use the previous energy output settings as default settings in the absence of any suitable signal indicating that the energy output of the focuses energy source is to be changed from the default settings. However, the system may as desired include the production of a NUL signal which NUL signal may be sent to the appropriate controller to confirm that no change is to be made to the previous power output settings of the focused energy source. Thus FIG. 14 also includes an optional dotted line 150 which is indicative of the connection between the stage wherein there is manipulation of focused energy output from the heating laser and the detection of the reflected probe signal which gives rise to the “observed electronic signal” wherein a NUL signal is exploited.

FIGS. 15 illustrates a schematic graphic representation of example saw tooth type laser heating pulses of varying power for modifying the laser energy output of the heating laser, each of the saw tooth pulses having a start time T₀ and a finish time T_{F} but wherein the maximum laser energy output of each pulse is different;

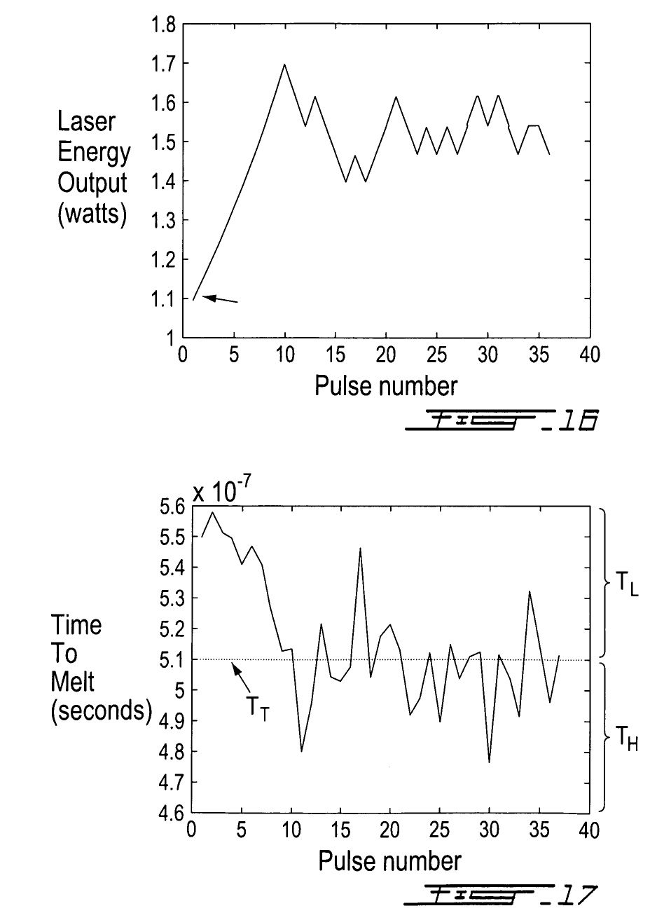

FIG. 16 illustrates an example schematic graphic representation of heating laser energy (i.e. power) output as a function of pulse number during an iterative control of the heating laser output; and

FIG. 17 illustrates example measured times (T) to initiate melting (i.e. time elapsing from T₀ to a slope change indicative of melting) as a function of pulse number during an iterative control of the heating laser output.

The characteristics of the heating pulses which may be modified to adjusted power output are varied. Thus, for example, the power of the focused heating source may be decreased or increased, the length of the application of the heating pulse may be decreased or increased, the temporal shape of the heating source pulse may be modified (see for example FIG. 15), the diameter of the beam of the heating pulse may be decreased or increased, all in order to bring the applied energy as close as desired to a required or necessary result. Further, the angle of application of the heating source may be varied, i.e. varied from a 90° angle to the semiconductor component.

1. A system for the controlled dopant profile modification of a pre-selected target region of a semiconductor component by the application of one or more heat treatments to said pre-selected target region, wherein said pre-selected target region comprises a first region contiguous with a second region, said first region having a heat modifiable dopant profile, said second region having a heat modifiable dopant profile different from said first region,
said system comprising a heat treatment component comprising a focused heating source for providing a focused energy output, said heat treatment component being configured for subjecting said pre-selected region to a heat treatment wherein said focused energy output
is directed to said pre-selected target region for a pre-determined duration having a start time and a finish time and
is sufficient to melt said pre-selected target region to form a melted region in a melt state
so as to thereby alter the dopant profile of the melted preselected target region,
characterized in that said system comprises a probe component for producing a control signal as a function of a reflected probe signal from said melted region,
said probe component comprising:
a) a probe signal generating component for directing a probe output signal to said pre-selected target region;
and
b) a reflected probe signal component comprising
i) a probe signal detector element for receiving a reflected probe signal generated by said probe output signal at said pre-selected target region, and for converting said reflected probe signal to an observed electronic signal initiated at said start time; and
ii) an electronic signal analyzer element for comparing said observed electronic signal with a predetermined target reflection signal having a target melt component indicative of said melted state, to determine if said observed electronic signal has a respective melt component which is synchronous or asynchronous with the target melt component of said predetermined target reflection signal, said electronic signal analyzer element producing at least one control signal selected from the group consisting of a leading signal if the melt component of said observed electronic signal leads the target melt component of said predetermined target reflection signal and a lagging signal if the melt component of said observed electronic signal lags the target melt component of said predetermined target reflection signal.

2. A system as defined in claim 1 wherein said probe component is a probe control component for controlling said heat treatment component as a function of said reflected probe signal from said melted region and further comprises
an electronic control element for directing said heat treatment component, when said heat treatment is repeated, to manipulate or modify, in response to said control signal and in predetermined manner, the focused energy output for a subsequent heat treatment.

3. A system as defined in claim 1 wherein said electronic signal analyzer element produces a leading signal if the melt component of said observed electronic signal leads the target melt component of said predetermined target reflection signal.

4. A system as defined in claim 1 wherein said electronic signal analyzer element produces a lagging signal if the melt component of said observed electronic signal lags the target melt component of said predetermined target reflection signal.

5. A system as defined in claim 1 wherein said electronic signal analyzer element produces a leading signal if the melt component of said observed electronic signal leads the target melt component of said predetermined target reflection signal and a lagging signal if the melt component of said observed electronic signal lags the target melt component of said predetermined target reflection signal.

6. A system as defined in claim 3 wherein said probe component is a probe control component for controlling said heat treatment component as a function of said reflected probe signal from said melted region and further comprises
an electronic control element for directing said heat treatment component, when said heat treatment is repeated, to decrease said focused energy output for a subsequent heat treatment in a predetermined manner, in response to said leading electronic signal.

7. A system as defined in claim 4 wherein said probe component is a probe control component for controlling said heat treatment component as a function of said reflected probe signal from said melted region and further comprises
an electronic control element for directing said heat treatment component, when said heat treatment is repeated, to increase said focused energy output for a subsequent heat treatment in a predetermined manner, in response to said lagging electronic signal.

8. A system as defined in claim 5 wherein said probe component is a probe control component for controlling said heat treatment component as a function of said reflected probe signal from said melted region and further comprises
an electronic control element for directing said heat treatment component, when said heat treatment is repeated, to respectively decrease or increase said focused energy output for a subsequent heat treatment in a predetermined manner, in response to said leading electronic signal or said lagging electronic signal.

9. A method for the controlled dopant profile modification of a pre-selected target region of a semiconductor component by the application of one or more heat treatments to said pre-selected target region, wherein said pre-selected target region comprises a first region contiguous with a second region, said first region having a heat modifiable dopant profile, said second region having a heat modifiable dopant profile different from said first region,
said method comprising subjecting said pre-selected region to a heat treatment wherein a focused energy output from a heat treat component comprising a focused heating source for providing said focused energy,
is directed to said pre-selected region for a pre-determined duration having a start time and a finish time and
is sufficient to melt said pre-selected region to form a melted region in a melt state
so as to thereby alter the dopant profile of the melted pre-selected target region,
characterized in that said method comprises a probe stage for producing a control signal as a function of a reflected probe signal from said melted region,
said probe stage comprising:
a) directing a probe output signal from a probe signal generating component to said pre-selected region;
b) detecting a reflected probe signal generated by said probe output signal at said pre-selected region, and converting said reflected probe signal to an observed electronic signal initiated at said start time;
c) comparing said observed electronic signal with a predetermined target reflection signal having a target melt component indicative of said melted state, to determine if said observed electronic signal has a respective melt component which is synchronous or asynchronous with the target melt component of said predetermined target reflection, and
d) producing at least one control signal selected from the group consisting of a leading signal if the melt component of said observed electronic signal leads the target melt component of said predetermined target reflection signal and a lagging signal if the melt component of said observed electronic signal lags the target melt component of said predetermined target reflection signal.

10. The method of claim 9 wherein said probe stage is a probe control stage for controlling said heat treatment component as a function of a reflected probe signal from said melted region, wherein said heat treatment is repeated one or more additional times, and wherein, for a subsequent heat treatment, said focused energy output is manipulated or modified in predetermined manner in response to said control signal (i.e. the control signal derived from a preceding heat treatment).

11. The method of claim 9 wherein said probe stage produces a leading signal if the melt component of said observed electronic signal leads the target melt component of said predetermined target reflection signal.

12. The method of claim 9 wherein said probe stage produces a lagging signal if the melt component of said observed electronic signal lags the target melt component of said predetermined target reflection signal.

13. The method of claim 9 wherein said probe stage produces a leading signal if the melt component of said observed electronic signal leads the target melt component of said predetermined target reflection signal and a lagging signal if the melt component of said observed electronic signal lags the target melt component of said predetermined target reflection signal.

14. The method of claim 11 wherein said probe stage is a probe control stage for controlling said heat treatment component as a function of a reflected probe signal from said melted region, wherein said heat treatment is repeated one or more additional times, and wherein for a subsequent heat treatment, said focused energy output is decreased, in predetermined manner, in response to said leading electronic signal.

15. The method of claim 14 wherein said focused energy output is decreased, in predetermined manner, in response to said leading electronic signal so as to induce the melt component of said observed electronic signal to at least approach the target melt component of said predetermined target reflection signal.

16. The method of claim 12 wherein said probe stage is a probe control stage for controlling said heat treatment component as a function of a reflected probe signal from said melted region, wherein said heat treatment is repeated one or more additional times, and wherein for a subsequent heat treatment, said focused energy output is increased, in predetermined manner, in response to said lagging electronic signal.

17. The method of claim 16 wherein said focused energy output is increased, in predetermined manner, in response to said leading electronic signal so as to induce the melt component of said observed electronic signal to at least approach the target melt component of said predetermined target reflection signal.

18. The method of claim 13 wherein said probe stage is a probe control stage for controlling said heat treatment component as a function of a reflected probe signal from said melted region, wherein said heat treatment is repeated one or more additional times, and wherein, for a subsequent heat treatment, said focused energy output is respectively decreased or increased, in predetermined manner, in response to said leading electronic signal or said lagging electronic signal.

19. The method of claim 18 wherein said focused energy output is respectively decreased or increased, in predetermined manner, in response to said leading electronic signal or said lagging electronic signal so as to induce the melt component of said observed electronic signal to at least approach the target melt component of said predetermined target reflection signal.
